(19) United States
(12) Patent Application Publication
(10) Pub. No.: US 2026/0088589 A1
(43) Pub. Date: Mar. 26, 2026

(54) Semiconductor Laser and Two-Channel Laser Array

(71) Applicant: NTT, Inc., Tokyo (JP)

(72) Inventors: Nikolaos-Panteleimon Diamantopoulos, Musashino-shi, Tokyo (JP); Shinji Matsuo, Musashino-shi, Tokyo (JP)

(21) Appl. No.: 19/109,633

(22) PCT Filed: Sep. 12, 2022
(86) PCT No.: PCT/JP2022/034003

§ 371 Date: Mar. 7, 2025

(51) Int. Cl. H01S 5/125

(52) U.S. Cl. CPC H01S 5/125

(57) ABSTRACT

A semiconductor laser includes a distributed feedback (DFB) region including an active layer and a uniform grating and two distributed Bragg reflector (DBR) region including an core layer and a uniform grating and optically coupled to respective ends of the DFB region and lengths of the DFB region and the DBR regions in a waveguide direction are set so that a photon-photon resonance frequency is in a range from 40 GHz to 50 GHz when an operating temperature is between 25 degrees and 75 degrees. The semiconductor laser optimizes a PPR effect and enables maximizing a modulation bandwidth.

### TECHNICAL FIELD

The present invention relates to a semiconductor laser that can be used for data transmission by direct modulation of a laser light over an optical fiber or within a photonic integrated circuit (PIC).

### BACKGROUND ART

Due to the surging traffic in data center networks and high-performance computing systems, future standardizations such as the Terabit Ethernet (TbE) will rely on data rates of 800 Gbps or 1.6 Tbps using multiple transmission lanes with more than 100 Gbps/lane.

In order to achieve this in a cost-effective and power-efficient manner, low energy consumption photonic integrated circuits (PICs) are expected to play a significant role in short-reach links with distances of 10 km or less. Such links will operate in the O-band telecommunications window, which corresponds to a lasing wavelength around 1.3 micrometers.

In particular, all PIC-based transmitters (Tx) and receivers (Rx) should also operate at a wide temperature range between 25 and 75 degrees Celsius and should also have a small size/footprint. Each Tx-Rx pair is expected to use several spatial or wavelength channels, in multiplexing schemes which are called space-division multiplexing (SDM) or wavelength-division multiplexing (WDM), respectively. The number of channels in each Tx-Rx would be 4, 8, 16, or 32 channels.

These requirements can be supported by high-speed and energy-efficient directly-modulated lasers (DMLs) operating in the O-band. Such DMLs are typically based on InP technology and can have a distributed reflector (DR) longitudinal structure composed of various distributed feedback (DFB) and distributed Bragg reflector (DBR) regions.

### CITATION LIST

### Patent Literature

PTL 1: Japanese Patent NO.6588859
PTL 2: Japanese Patent NO.6927153

### Non Patent Literature

NPL 1: G. Morthier, et al., “Extended Modulation Bandwidth of DBR and External Cavity Lasers by Utilizing a Cavity Resonance for Equalization,” IEEE J. Quantum Electron., vol. 36, no. 12, pp. 1468-1475, December 2000.
NPL 2: M. Radziunas, et al., “Improving the Modulation Bandwidth in Semiconductor Lasers by Passive Feedback,” IEEE J. Sel. Top. Quantum Electron., vol. 13, no. 1, pp. 136-142, January-February 2007.
NPL 3: H. Dalir and F. Koyama, “Bandwidth enhancement of single-mode VCSEL with lateral optical feedback of slow light,” IEICE Electron. Expr., vol. 8, no. 13, pp. 1075-1081, July 2011.

### SUMMARY OF INVENTION

### Technical Problem

For the realization of DMLs with a low power consumption, typically a structure that achieves a high optical confinement structure is required. Such structures can be achieved by having a thin layer (less than 350 nm thickness) of III-V materials on top of a SiO₂/Si substrate. For DR-DMLs (Distributed Reflector-Directly Modulated Laser), the DFB region can include an active layer based on multi-quantum wells (MQWs).

For operation in the O-band, the MQWs of the active layer can be based on InGaAlAs compounds. Such structures can achieve a very high optical confinement factor.

And, it can also ensure low fabrication costs due to the availability of large Si wafers and established fabrication methods. In addition, Si waveguides can be coupled to the active MQW core for the realization of more complex silicon photonics (SiPh) PICs.

As described in PTL 1, a modulation bandwidth of the membrane DML is typically limited to a 3-dB-down value of around 20 GHz. In general, one way to increase the modulation bandwidth of any DML is to achieve a longitudinal laser design which enables the photon-photon resonance (PPR) effect via optical feedback (For. example, refer to PTL 2 and NPL 1-NPL 3). However, an optimized membrane DR-DML structure for maximizing the modulation bandwidth is not clear in these Literatures.

### Solution to Problem

To solve the above described problem, a semiconductor laser of the present invention comprises a distributed feedback region including an active layer and a first uniform grating, a first distributed Bragg reflector region including a core layer and a second uniform grating, the first distributed Bragg reflector region optically coupled to one end of the distributed feedback region in a waveguide direction, and a second distributed Bragg reflector region including a core layer and a third uniform grating, the second distributed Bragg reflector region optically coupled to the other end of the distributed feedback region in a waveguide direction, wherein a length of the distributed feedback region, a length of the first distributed Bragg reflector region and a length of the second distributed Bragg reflector region in a waveguide direction are set so that a photon-photon resonance frequency of the semiconductor laser is in a range from 40 GHz to 50 GHz when an operating temperature is between 25 degrees Celsius and 75 degrees Celsius.

### Advantageous Effects of Invention

According to the present invention, the membrane DR-DML structure which optimizes the PPR effect can be achieved and enables maximizing the modulation bandwidth at an operating temperature range between 25 and 75 degrees Celsius. Furthermore, based on this membrane DR-DML structure, a two-channel laser array can be achieved for supporting 200 (2×112) Gbps NRZ (Non Return to Zero) and 400 (2×200) Gbps PAM-4(Pulse Amplitude Modulation-4) in the O-band communications window with low power consumptions.

### BRIEF DESCRIPTION OF DRAWINGS

FIG. 1 is a chart for showing a structure of a semiconductor laser according to an embodiment of the present invention;

FIG. 2 is a chart for showing a longitudinal cross-sectional view of a semi-conductor laser according to the embodiment of the present invention;

FIG. 3 is a chart for showing a transverse cross-sectional view of a distributed feedback (DFB) region of a semiconductor laser according to the embodiment of the present invention;

FIG. 4 is a chart for showing transverse cross-sectional view of a distributed reflector (DBR) region of a semiconductor laser according to the embodiment of the present invention.

FIG. 5 is a graph for showing the relationship between damping and wavelength separation in a semiconductor laser according to the embodiment of the present invention;

FIG. 6 is a graph for showing a relationship between a resonance frequency and a length of a distributed feedback region in a semiconductor laser according to the embodiment of the present invention;

FIG. 7 is a graph for showing carrier density dependence of gain in a semi-conductor laser according to the embodiment of the present invention;

FIG. 8 is a graph for showing simulation results of the frequency dependence of the E-O response in a semiconductor laser according to the embodiment of the present invention;

FIG. 9 is a chart for showing an example configuration of a 2-channel laser array using a semiconductor laser according to the embodiment of the present invention;

FIG. 10A is a graph for showing measured L-I-V characteristics in a 2-channel laser array according to the embodiment of the present invention;

FIG. 10B is a graph for showing measured L-I-V characteristics in a 2-channel laser array according to the embodiment of the present invention;

FIG. 11 is a graph for showing spectrum measurement results in a 2-channel laser array according to the embodiment of the present invention according to the embodiment of the present invention;

FIG. 12A is a graph for showing measured frequency dependence of E-O response according to the embodiment of the present invention;

FIG. 12B is a graph for showing measured frequency dependence of E-O response according to the embodiment of the present invention;

FIG. 12C is a graph for showing measured frequency dependence of E-O response according to the embodiment of the present invention;

FIG. 13A is a chart for showing measurement results of eye patterns according to the embodiment of the present invention;

FIG. 13B is a chart for showing measurement results of eye patterns according to the embodiment of the present invention;

FIG. 13C is a chart for showing measurement results of eye patterns according to the embodiment of the present invention; and

FIG. 14 is a graph for showing results of BER measurements according to the embodiment of the present invention.

### DESCRIPTION OF EMBODIMENTS

Embodiments for implementing the present invention is demonstrated using figures. The present inventions are not limited by the following embodiments.

### First Embodiment

### Structure of Semiconductor Laser

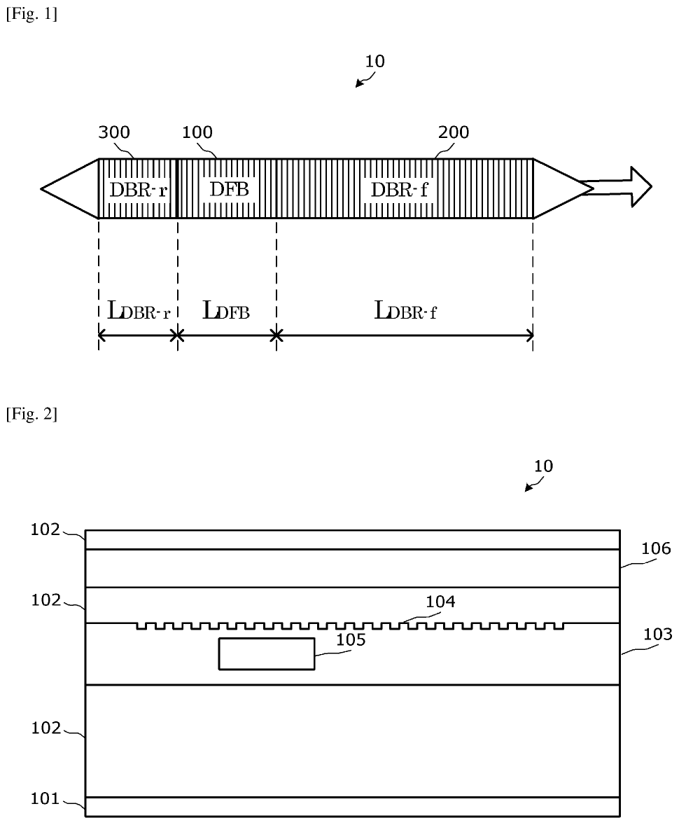

A structure of a semiconductor laser according to the embodiment of the present invention is shown in FIG. 1. The semiconductor laser 10 of this embodiment has a membrane DR-DML structure with a distributed feedback (DFB) region 100 and two distributed reflector regions (DBR-f region 200 and DBR-r region 300) optically coupled to a waveguide direction edge of the DFB region 100.

The membrane DR-DML structure of this embodiment is composed of the DFB region 100 which is sandwiched by the short DBR-r region 300 and the long DBR-f region 200 in the waveguide direction. A Laser light is emitted mainly from a facet near the DBR-f region 200.

A cross-sectional view of the semiconductor laser of this embodiment in the waveguide direction is shown in FIG. 2. The DFB region 100 of the semiconductor laser 10 of this embodiment comprises an active layer 105 formed on a Si substrate and a uniform diffraction grating 104 (a first diffraction grating) with a uniform period formed on the active layer 105.

The DBR-f region 200 (a first distributed reflector region) optically coupled to one end of the waveguide direction of the DFB region 100 comprises a core layer 103 continuously formed in the active layer 105 and a uniform diffraction grating 104 (a second diffraction grating) formed on the core layer 103.

The DBR-r region 300 (a first distributed reflector region) optically coupled to the other end of the waveguide direction of the DFB region 100 comprises a core layer 103 continuously formed in the active layer 105 and a uniform diffraction grating 104 (a second diffraction grating) formed on the core layer 103.

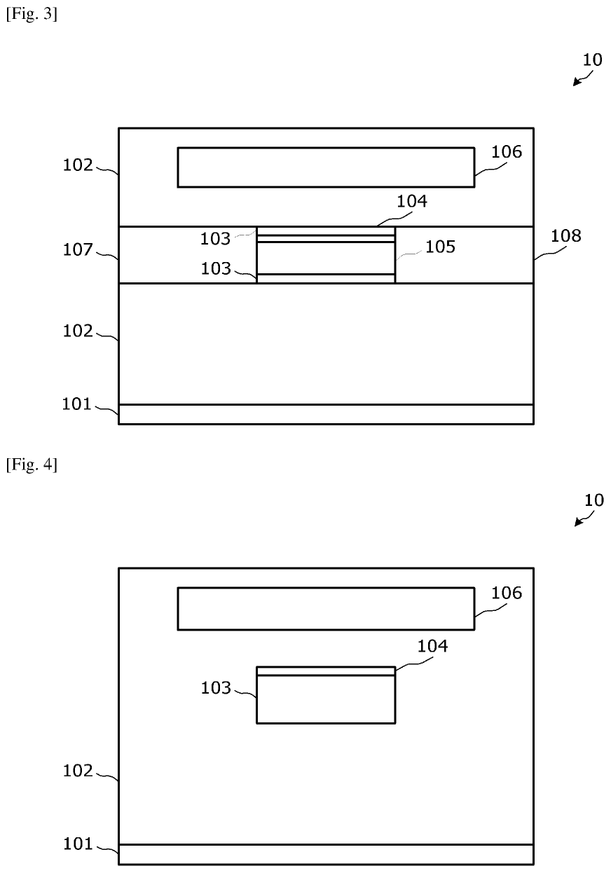

Cross-sectional views of this semiconductor laser of this embodiment in the transverse direction relative to the waveguide direction are shown in FIGS. 3 and 4. The active layer 105 in the DFB region 100 has a quantum well (MQW) structure. The active layer 105 has a 6-period quantum wells structure based on InGaAlAs compounds. For example, a core width of the active layer 105 is 600 nm, which is not limited to this value.

The active layer 105 is sandwiched between a p-type InP layer 107 and an n-type InP layer 108. Direct modulation to a laser beam is performed via electrodes formed on the p-type InP layer 107 and the n-type InP layer 108.

The active layer 105 is surrounded by InP layer 103. A total thickness of III-V layer (105, 103]) is less than 350 nm, which is not limited to this value. The III-V layer (105, 103]) is composed on SiO₂ layer 102 on the Si substrate 101.

The SiO₂ layer 102 is also used as an under-cladding for the active layer 105. The under-cladding can include additional low-refractive index materials such as SiOₓ and BCB. Similarly, an over-cladding 102 can be also composed of SiO₂ and/or other low-refractive index materials such as SiOₓ and BCB.

Coupling coefficients and bragg wavelengths of the DFB region 100 and the DBR regions (DBR-f 200, DBR-r 300) are controlled by the gratings 104 formed by peri-odically etching the top of InP layer 103.

For low-loss edge-coupling to optical fibers, an SiOₓ waveguide 106 with a 3 micrometers×3 micrometers core, for example, is fabricated on top of the InP layer 103 which is surrounded by the cladding layer 102.

Efficient coupling from the III-V layer (105, 103) to the SiOₓ waveguide 106 is achieved by having an InP-based taper waveguide with a maximum width of 1.5 micrometers without any surface InP grating 104. Such InP tapers could be located on both sides of the longitudinal laser structure, as shown in FIG. 1.

The DBR regions (DBR-f 200, DBR-r 300) can be composed of a similar 1.5 micrometer-wide InP waveguides which include uniform periodic surface gratings 104.

The length of the DFB region 100 (LDFB) can be, for example, 60 micrometers to 120 micrometers. The lengths of the DBR-r region 300 (LDBR-r) and the DBR-f region 200 (LDBR-f) can be, for example, 80 micrometers and 200 micrometers, respectively.

The coupling coefficient of both DBR regions (DBR-f 200, DBR-r 300) can be, for example, around 400 cm⁻¹, while the coupling coefficient of the DFB region 100 can be, for example, 400 cm⁻¹ to 550 cm⁻¹. For operation in the O-band communications window, the Bragg wavelengths of the DFB and DBR regions should be around 1.3 micrometers.

The Bragg wavelength detuning between the DBR-f region 200 and the DFB region 100 should be within ±1 nm, while the Bragg wavelength of the DBR-r region 300 should be between +4 nm and +7 nm in respect to the Bragg wavelength of the DFB region 100.

This DR-DML structure ensures a single-longitudinal-mode operation with small hole-burning effects, and lasing at the longer-wavelength side of the DFB region 100 and DBR-f region 200 transmittance and reflectance spectra. The intrinsic modulation bandwidth can be further enhanced by detuned loading effect between a frequency of PPR (f_{PPR}) and a relaxation oscillation frequency (f_{R}).

### Optimizing the PPR Effect

For optimizing the PPR effect and enhancing the modulation bandwidth, it is necessary to optimize the frequency of the PPR effect (f_{PPR}) which is proportional to a wavelength separation between the main lasing mode and its first longitudinal side-mode generated by optical feedback.

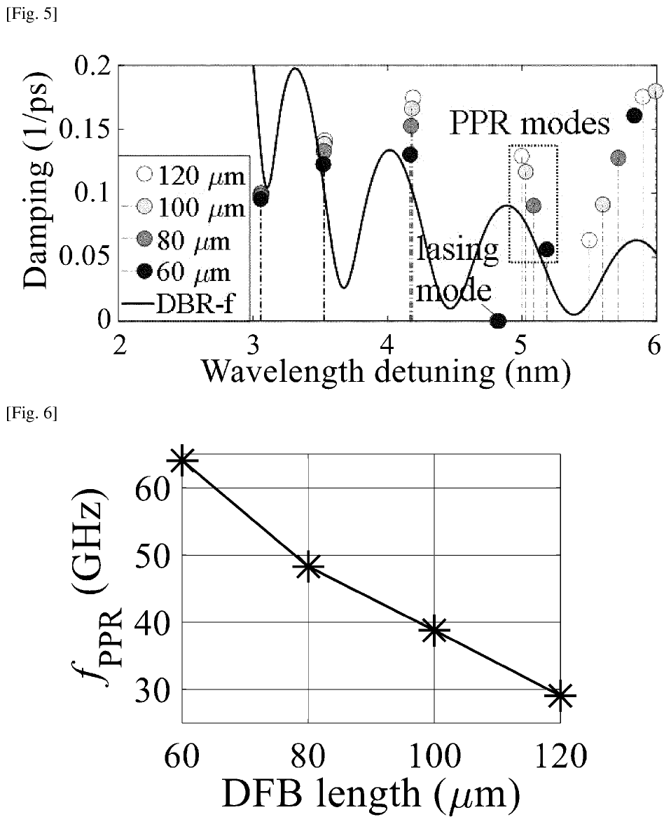

In the membrane DR-DML structure, the f_{PPR} can be tuned by varying L_{DFB}. FIG. 5 shows a simulated longitudinal mode analysis for L_{DFB} between 60 micrometers and 120 micrometers around operating bias conditions.

One important point on maximizing the modulation bandwidth is to achieve a uniform E-O response with the PPR effect. This means that the f_{PPR} value should be optimized in respect to the relaxation oscillation frequency (f_{R}).

A large frequency separation between f_{PPR} and f_{R} could result in a large dip in the E-O response, while a small frequency separation could result in a 3-dB bandwidth which is smaller than a potential maximum value.

According to examinations by the inventors in this present application, considering that the f_{R} of the membrane DR-DML is around 10 to 15 GHZ, the maximization of the modulation bandwidth should be achieved with f_{PPR}=50 GHz, approximately.

The relationship between the resonance frequency (f_{PPR}) and the length of DFB region in the semiconductor laser of this embodiment is shown in FIG. 6. In FIG. 6, the length of the DBR-f region (LDBR-f) is set to be 200 micrometers and the length of the DBR-r region (LDBR-r) is set to be 80 micrometers. FIG. 6 shows that the length of the DFB region (LDFB) corresponds to f_{PPR}=50 is approximately 80 micrometers.

In order to simulate and study the E-O response of the proposed structure in this embodiment, a relationship of gain in respect to carrier densities at operating temperatures between 25 and 75 degrees Celsius were extracted from a fabricated membrane DR-DML. FIG. 7 shows a carrier density dependence of gain in the semiconductor laser in this embodiment.

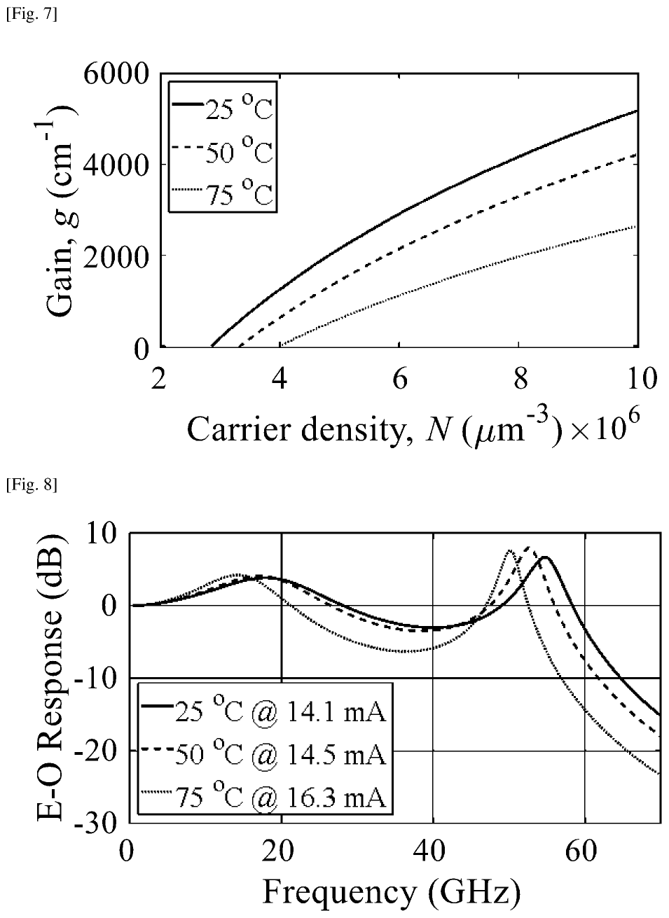

Based on the carrier density dependence of the gain in FIG. 7, numerical simulations were performed based on a travelling-wave laser simulator. FIG. 8 shows that the E-O responses of the membrane DR-DML structure with L_{DFB}=80 micrometers were plotted for operating temperatures between 25 and 75 degrees Celsius.

According to FIG. 8, the expected 3-dB bandwidth at 25 degrees Celsius is around 60 GHz. It can be seen that the PPR effect can be optimized and the 3 dB bandwidth can be enhanced by adjusting the length of the DFB region (L_{DFB}).

According to FIG. 8, both f_{PPR} and f_{R} decrease at higher operating temperatures. When the operating temperature increases, the frequency separations of f_{PPR} and f_{R} remain within a suitable range for maximization of the E-O response by adjusting an operating bias current.

It can be seen in the simulations of FIG. 8 that at operating temperatures from 25 to 75 degrees Celsius, the relaxation oscillation frequency (f_{R}) is approximately 15 to 20 GHz, and the resonance frequency (f_{PPR}) is approximately 50 to 55 GHz. The frequency separations of f_{PPR} and f_{R} remain around 35 GHZ.

Furthermore, the operating bias currents for maximizing the modulation bandwidths remain within ±1-2 mA at operating temperatures from 25 to 75 degrees Celsius

This means that any integration of heaters or phase-shifters within a DR structure are not required for tuning the PPR effect at different operating temperatures.

Instead, slow and cheap control electronics typically found in DML-Txs could be used for temperature monitoring and bias current adjustment within a Tx module.

### Experimental Results With 2-Channel Laser Array

In order to validate a performance of the proposed membrane DR-DML structure ex-perimentally, we have fabricated a two-channel laser array based on 80 micrometer-long DFB region by using our in-house membrane-III-V-on-Si technology.

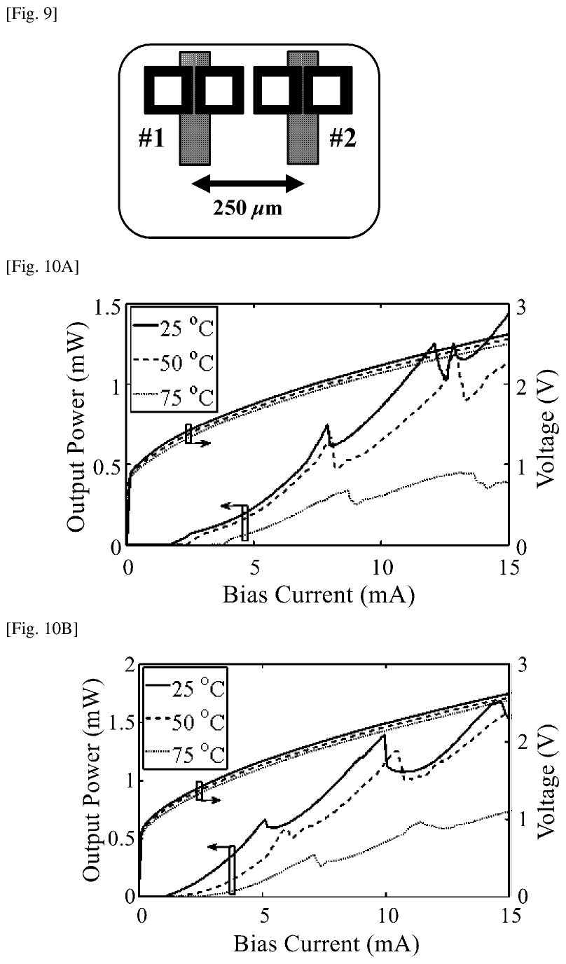

A schematic of the two-channel laser array using the semiconductor laser of this embodiment is shown in FIG. 9. In FIG. 9, two membrane DR-DMLs with lateral p-n junctions are fabricated with a laser pitch of 250 micrometers.

The L-I-V characteristics of the two-channel laser array are shown in FIGS. 10A and 10B. The measurements were performed by using a high-numerical aperture fiber (HNAF) which was fusion-spliced together with a standard single-mode fiber (SSMF) pigtail, and butt-coupled to the chip front facet. FIGS. 10a and 10b show results of the measurements at CH#1 and CH#2 in FIG. 9, respectively.

Super-linear behaviors on L-I curves are obtained similarly to previously reported DR-DMLs with the PPR effect. Kinks in the L-I curve correspond to mode hopping between the lasing mode and the first PPR side-mode. Output powers of more than 1 mW were obtained for both CH#1 and CH#2.

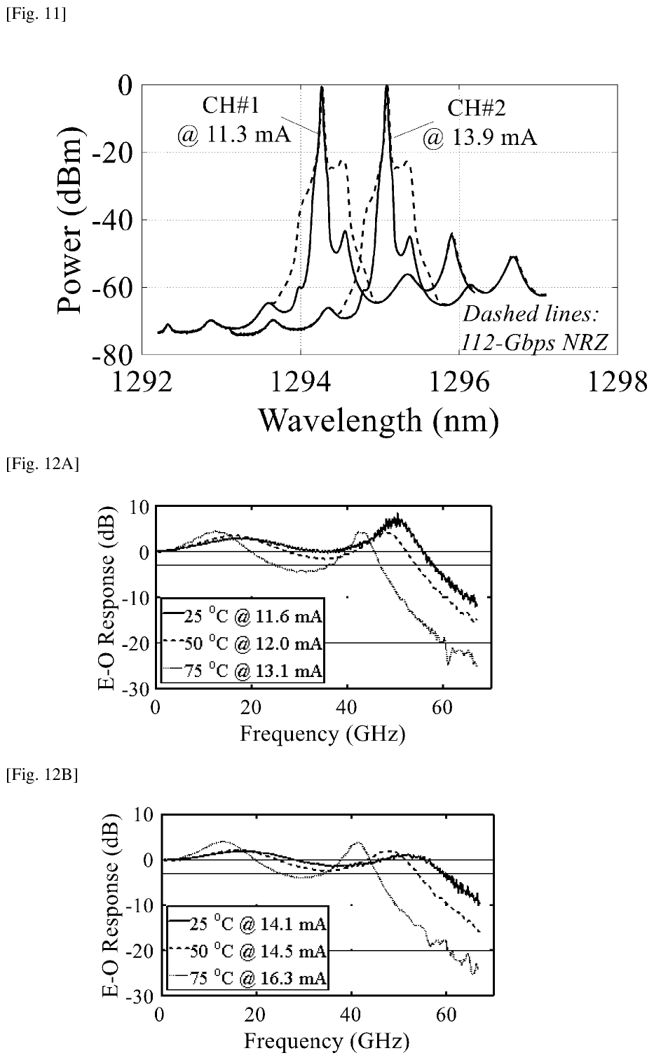

FIG. 11 shows spectrum measurement results for the two-channel laser array. Solid lines correspond to static measurements and dashed lines correspond to dynamic measurements. The dynamic measurements were based on 112-Gbps NRZ signals. A small variation in the Bragg wavelengths CH#1 and CH#2 due to fabrication resulted in slightly different lasing wavelengths.

According to FIG. 11, PPR side-mode appears next to the lasing mode for both channels, which effectively amplify the modulated signals. The existence of the PPR effect for enhancing the modulation bandwidth was confirmed.

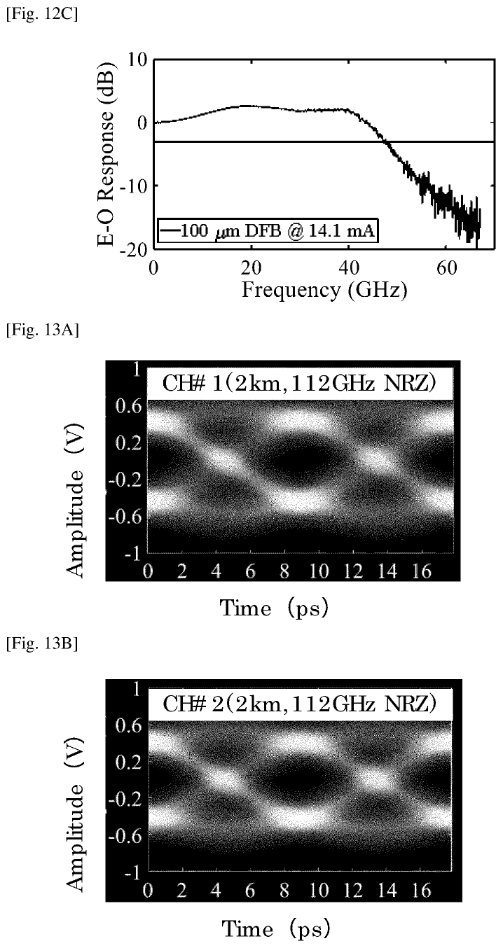

FIGS. 12A, 12B and 12c show measured frequency dependence of the E-O response in the embodiment of the present invention. FIGS. 12A and 12B show measured E-O responses for the two channels of membrane DR-DMLs with an 80 micrometer-long DFB region. FIG. 12C shows a measured E-O response for another membrane DR-DML with a 100 micrometer-long DFB region fabricated within the same fabrication wafer.

According to FIGS. 12A and 12B, both channels of the membrane DR-DML with an 80 micrometer-long DFB region exhibit a 3-dB bandwidth of around 60 GHz at the operation temperature 25 degrees Celsius. On the other hand, according to FIG. 12C, the DR-DML with 100 micrometer-long DFB region exhibit the 3-dB bandwidth of around 50 GHz. It was confirmed that the 3-dB bandwidth could be enhanced by adjusting the length of DFB region 100.

According to FIGS. 12A and 12B, the values of f_{PPR} are 50 GHz for the two-channel array the DR-DML with an 80 micrometer-long DFB region at an operating temperature 25 degrees Celsius. On the other hand, the value of f_{PPR} is 40 GHz for the DR-DML with 100 micrometer-long DFB region. These results match theoretical values in FIG. 6.

According to FIGS. 12A and 12B, f_{R} decrease at higher operating temperatures, while f_{PPR} decreases accordingly. For example, in FIG. 12A, f_{R} is approximately 10 to 20 GHz, while f_{PPR} is approximately 40 to 50 GHz at operating temperatures from 25 degrees Celsius to 75 degrees Celsius.

As expected from the simulated results in FIG. 8, when the operating temperature increases, the frequency separations of f_{PPR} and f_{R} remain within a suitable range for maximization of the E-O response by adjusting an operating bias current. In FIGS. 12A and 12B, the frequency separations of f_{PPR} and f_{R} remain approximately 30 to 35 GHz.

### Data Transmission Experiment in 2-Channel Laser Array

In the two-channel laser array, data transmission experiments are performed using 112-Gbps NRZ (non-return-to-zero) and 200-Gbps PAM-4 (4-level pulse-amplitude modulation) signals at a stage controlled temperature of 25 degrees Celsius.

In the data transmission experiments, in a transmitter side, signals were generated by an arbitrary waveform generator and they are applied to the two-channel array using RF cables, an RF driver, a bias-tee, and an RF probe. In a receiver side, the signals were detected by using a photodiode, an RF amplifier and a real-time oscilloscope.

These measurements were carried out at an optical back-to-back (BTB) configuration and a configuration that signals were detected after 2-km transmissions over SSMF (2 km SSMF).

All components consisting the signal generation and detection had sufficient bandwidths of minimum 60 GHz. And offline digital equalization was performed in order to mitigate linear and nonlinear impairments.

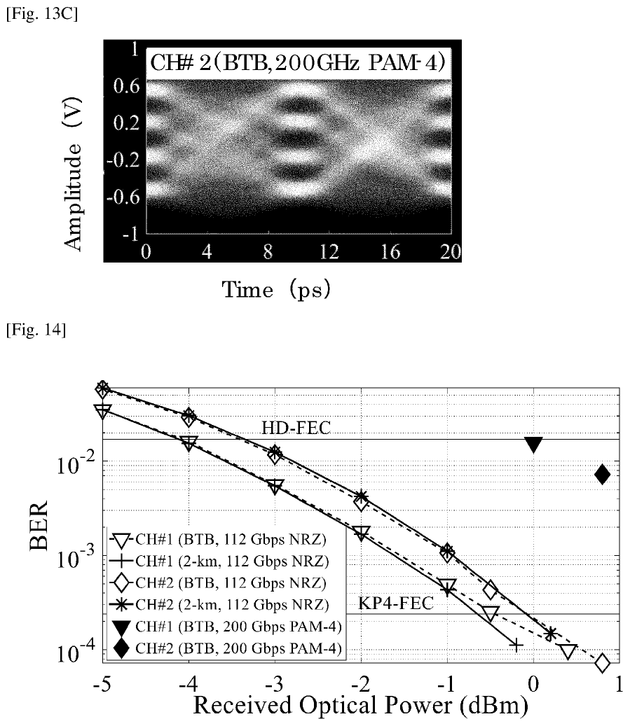

FIGS. 13A and 13B show eye diagrams for 112 Gbps NRZ signals after 2 km SSMF transmissions for CH#1 and CH#2. FIG. 13C show an eye diagram for 200 Gbps PAM-4 signals in the BTB configuration for CH#2. Eye apertures are observed in eye diagrams shown in FIGS. 13A, 13B and 13C.

The resulting bit-error rates (BERs) are summarized in FIG. 14. A total data rate of 200 (2×112) Gbps could be achieved with NRZ signals after 2 km SSMF transmissions under a KP4-FEC (KP4 forward error correction, used in IEEE 200/400-Gbps Ethernet std.) threshold of 2.4×10⁻⁴.

Regarding 200 Gbps PAM-4 signals at BTB configuration, BER could not reach KP4-FEC threshold of 2.4×10⁻⁴. However, under a HD-FEC (hard-decision forward error correction) threshold of 1.71×10⁻², 400 (2×200) Gbps could be achieved with PAM-4 signals at BTB configuration.

The operating bias currents and voltages for the two channels were 11.3 mA and 2.347 V for CH#1 and 13.9 mA and 2.517 V for CH#2. The operating powers were around 26.5 mW and 35.0 mW for CH#1 and CH#2, respectively, denoting a total of less than 0.3 pJ/bit for the 200-Gbps NRZ signals. Low laser operating power of less than 0.3 pJ/bit could be achieved by the present invention.

### Other Embodiments

The DFB region 100 of the embodiment of the present invention can have a coupled Si waveguide for coupling to silicon photonic chips below or under the III-V layer.

The DFB region 100 of the embodiment of the present invention can be biased using either a lateral p-n junction or a vertical p-n junction.

Instead of using SiO₂/Si substrate of the embodiment of the present invention, other substrates such as InP can be used.

The cladding layers 102 can be based on other low-index materials such as SiOₓ, BCB, SiO₂, etc. and their combinations.

The uniform diffraction grating 104 of the embodiment of the present invention can be achieved also by other means such as depositing and etching an additional membrane such as SiN.

### INDUSTRIAL APPLICABILITY

Data-center and high-performance computing interconnections utilizing PICs, and short-reach optical communication links.

### REFERENCE SIGNS LIST

100 DFB Region
101 Si substrate
102 SiO₂ layer
103 InP layer
104 Diffraction grating
105 Active layer
106 SiOₓ layer
107 p-type InP layer
108 n-type InP layer
200 DBR-f Region
300 DBR-r Region

1. A semiconductor laser, comprising
a distributed feedback region including an active layer and a first uniform grating;
a first distributed Bragg reflector region including a core layer and a second uniform grating, the first distributed Bragg reflector region optically coupled to one end of the distributed feedback region in a waveguide direction; and
a second distributed Bragg reflector region including a core layer and a third uniform grating, the second distributed Bragg reflector region optically coupled to the other end of the distributed feedback region in a waveguide direction,
wherein a length of the distributed feedback region, a length of the first distributed Bragg reflector region and a length of the second distributed Bragg reflector region in a waveguide direction are set so that a photon-photon resonance frequency of the semiconductor laser is in a range from 40 GHz to 50 GHz when an operating temperature is between 25 degrees Celsius and 75 degrees Celsius.

2. The semiconductor laser according to claim 1, wherein a frequency separation between a relaxation oscillation frequency of the semiconductor laser and the photon-photon resonance frequency is in a range from 30 GHz to 35 GHZ.

3. The semiconductor laser according to claim 1, wherein the length of the distributed feedback region, the length of the first distributed Bragg reflector region and the length of the second distributed Bragg reflector region in a waveguide direction are set so that the photon-photon resonance frequency is 50 GHz when the operating temperature is 25 degrees Celsius.

4. The semiconductor laser according to claim 1, wherein the length of the distributed feedback region, the length of the first distributed Bragg reflector region and the length of the second distributed Bragg reflector region in a waveguide direction are set to be 80 micrometers, 80 micrometers and 200 micrometers, respectively.

5. The semiconductor laser according to claim 1, wherein a 3 dB modulation bandwidth of the semiconductor laser is in a range from 40 GHz to 60 GHz.

6. The semiconductor laser according to claim 5, wherein the 3 dB modulation bandwidth of the semiconductor laser is 60 GHz when the operating temperature is 25 degrees Celsius.

7. A 2-channel laser array, comprising two semiconductor lasers of claim 1 which are arranged at a predetermined laser pitch, wherein each of the two semiconductor lasers is configured to transmit 112 Gbps NRZ signals or 200 Gbps PAM-4 signals in an O-band communication window.

8. The 2-channel laser array according to claim 7, wherein an operation power is less than 0.3 pJ/bit, when the operating temperature is 25 degrees Celsius.

9. A semiconductor laser, comprising:
a cladding layer;
a core layer formed on the cladding layer;
a grating formed on the cladding layer; and
an active layer formed in the core layer; and
wherein the cladding layer, the grating and the active layer constitute
a distributed feedback region including the active layer and a first region of the grating formed in the first region of the core layer;
a first distributed Bragg reflector region including a second region of the core layer extending on one side of the active layer in a waveguide direction and a second region of the grating formed in the second region of the core layer, the first distributed Bragg reflector region optically coupled to one end of the distributed feedback region in the waveguide direction; and
a second distributed Bragg reflector region including a third region of the core layer extending on the other side of the active layer in the waveguide direction and a third region of the grating formed in the second region of the core layer, the second distributed Bragg reflector region optically coupled to the other end of the distributed feedback region in a waveguide direction,
wherein a length of the distributed feedback region, a length of the first distributed Bragg reflector region and a length of the second distributed Bragg reflector region in a waveguide direction are set so that a photon-photon resonance frequency of the semiconductor laser is in a range from 40 GHz to 50 GHz when an operating temperature is between 25 degrees Celsius and 75 degrees Celsius.
